(19) United States
(12) Patent Application Publication
(10) Pub. No.: US 2026/0282804 A1
(43) Pub. Date: Sep. 17, 2026

(54) ELECTROSTATIC CHUCK

(71) Applicant: TOTO LTD., Fukuoka (JP)

(72) Inventors: Yuki SASAKI, Fukuoka (JP); Jun SHIRAISHI, Fukuoka (JP); Ikuo ITAKURA, Fukuoka (JP); Rui IMOTO, Fukuoka (JP); Shunya MIYAZAKI, Fukuoka (JP)

(73) Assignee: TOTO LTD., Fukuoka (JP)

(21) Appl. No.: 19/539,399

(22) Filed: Feb. 13, 2026

(30) Foreign Application Priority Data
Mar. 14, 2025 (JP) 2025-041383

(51) Int. Cl. H10P 72/00; H10P 72/72; H10P 72/76

(52) U.S. Cl. CPC H10P 72/0434; H10P 72/0421; H10P 72/72; H10P 72/722; H10P 72/7614; H10P 72/7616

(57) ABSTRACT

An electrostatic chuck 10 includes a dielectric substrate 100 including a placement surface, and a plurality of conductor layers provided at mutually different height positions inside the dielectric substrate 100. When a total thickness of the respective conductor layers is defined as sd (μm) and a thickness of the dielectric substrate 100 is defined as D (mm), the electrostatic chuck 10 satisfies the following condition: sd <-10.5×D +74.5.

### CROSS-REFERENCE TO RELATED APPLICATION

This application is based upon and claims the benefit of priority from Japanese Patent Application No. 2025-041383 filed on Mar. 14, 2025, the entire contents of which are incorporated herein by reference.

### FIELD

The present invention relates to an electrostatic chuck.

### BACKGROUND

For example, in a semiconductor manufacturing apparatus such as an etching apparatus, an electrostatic chuck is provided as an apparatus configured to attract and hold a wafer such as a silicon wafer to be processed. The electrostatic chuck includes a dielectric substrate provided with an attraction electrode. When a voltage is applied to the attraction electrode, an electrostatic force is generated, and the wafer placed on the dielectric substrate is attracted and held. The attraction electrode may be formed on a front surface on the base plate side of the dielectric substrate. However, for example, as described in Japanese Patent Laid-Open No. 2011-119654, the attraction electrode is provided inside the dielectric substrate as an attraction electrode layer in many cases.

An RF electrode layer may be provided in addition to the attraction electrode layer inside the dielectric substrate. The RF electrode layer is a conductor layer provided as one of a pair of counter electrodes for generating plasma in the semiconductor manufacturing apparatus. The other of the counter electrodes is provided at a position on an upper side relative to the electrostatic chuck in the semiconductor manufacturing apparatus.

In this manner, a plurality of conductor layers such as an attraction electrode layer and an RF electrode layer, for example, are provided inside the dielectric substrate. The plurality of conductor layers are arranged at mutually different height positions.

### SUMMARY

According to experiments and the like conducted by the present inventors, it has been found that when a total thickness of the respective conductor layers arranged at mutually different height positions inside the dielectric substrate becomes large, peeling may occur between the dielectric substrate and the conductor layers at the time of manufacturing the electrostatic chuck or the like, and a gap may be formed therebetween. As a result of further detailed investigation, it has been found that when an overall thickness of the dielectric substrate becomes large, the above-described peeling is more likely to occur.

The present invention has been made in view of such problems and aims at providing an electrostatic chuck that can suppress peeling between the dielectric substrate and the conductor layers.

To address the above-described problems, an electrostatic chuck according to the present invention includes a dielectric substrate including a placement surface on which an object to be processed is placed, and a plurality of conductor layers provided at mutually different height positions inside the dielectric substrate. When a total thickness of the respective conductor layers is defined as sd (μm) and a thickness of the dielectric substrate is defined as D (mm), the electrostatic chuck satisfies the following condition: sd<−10.5×D+74.5.

According to experiments and the like conducted by the present inventors, a new finding has been obtained that when a total thickness (sd) of the respective conductor layers and a thickness (D) of the dielectric substrate are set to satisfy the condition of sd<−10.5×D+74.5, peeling between the dielectric substrate and the conductor layers can be sufficiently suppressed.

According to the present invention, it is possible to provide an electrostatic chuck capable of suppressing peeling between the dielectric substrate and the conductor layers.

### BRIEF DESCRIPTION OF THE DRAWINGS

FIG. 1 is a cross-sectional view schematically illustrating a configuration of an electrostatic chuck according to the present embodiment;

FIG. 2 is an enlarged view of a part of the configuration in FIG. 1; and

FIG. 3 is a cross-sectional view schematically illustrating a configuration of an electrostatic chuck according to a modification.

### DETAILED DESCRIPTION

Hereinafter, the present embodiment will be described with reference to the accompanying drawings. To ease understanding of the descriptions, in each drawing, the same components are denoted by the same reference signs as much as possible, and duplicate descriptions are not repeated.

An electrostatic chuck 10 according to the present embodiment is configured to attract and hold a wafer W set as a process target by an electrostatic force inside a semiconductor manufacturing apparatus such as, for example, an etching apparatus which is not illustrated in the drawing. The wafer W that is an object to be processed is, for example, a silicon wafer. The electrostatic chuck 10 may be used in an apparatus other than the semiconductor manufacturing apparatus.

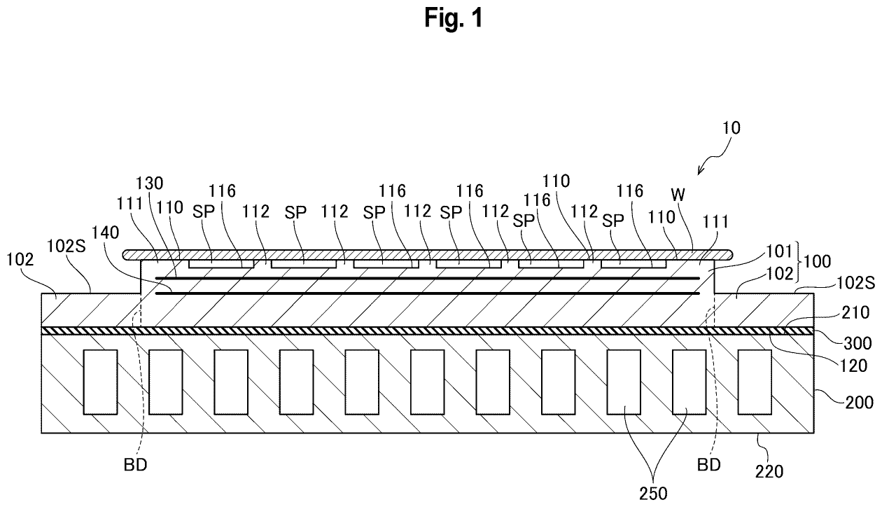

FIG. 1 is a cross-sectional view schematically illustrating a configuration of the electrostatic chuck 10 in a state in which the wafer W is attracted and held. The electrostatic chuck 10 includes a dielectric substrate 100 and a base plate 200.

The dielectric substrate 100 is a substantially disk-shaped member formed of a ceramic sintered body. The dielectric substrate 100 is formed of, for example, a material containing highly pure alumina (Al₂O₃) as a principal component. A ceramic purity or type, an additive, or the like in the dielectric substrate 100 may be appropriately set by taking into account plasma resistance or the like needed for the dielectric substrate 100 in the semiconductor manufacturing apparatus.

In the present specification, the term “principal component” refers to a compound that is confirmed to be contained in a target object in a relatively larger amount than any other compound contained therein, when quantitative or semi-quantitative analysis is performed on the target object such as the dielectric substrate 100 by X-ray Diffraction (XRD). A ratio occupied by alumina as the principal component is larger than 50% in the dielectric substrate 100 of the present embodiment. The ratio is more preferably equal to or larger than 90%, and even more preferably equal to or larger than 95%.

When alumina is used as a material of the dielectric substrate 100 as in the present embodiment, it is preferable that a purity of alumina used as a raw material in the dielectric substrate 100 is set to be equal to or larger than 99.5%. By increasing the purity of alumina to such a level, it is possible to sufficiently ensure durability of the dielectric substrate 100 against plasma.

A surface 110 on an upper side in FIG. 1 in the dielectric substrate 100 serves as a “placement surface” on which the wafer W, as a process target, is placed. A surface 120 on a lower side in FIG. 1 in the dielectric substrate 100 serves as a “surface to be joined” which is joined to the base plate 200 via a joining layer 300. A perspective in a case where the electrostatic chuck 10 is viewed from the surface 110 side along a direction perpendicular to the surface 110 will also be hereinafter expressed as “top view”.

The dielectric substrate 100 includes a first part 101 and a second part 102. The first part 101 is a substantially columnar part extending from the surface 110 toward a lower side in FIG. 1 to the surface 120. In the present embodiment, an end part on an outermost peripheral side of the surface 110 as the placement surface matches an end part on an outermost peripheral side of the first part 101 in top view. The first part 101 is a part including the surface 110 as the placement surface in the dielectric substrate 100.

The second part 102 is an annular part projecting from an outer peripheral end of the first part 101 further toward an outer peripheral side, which is also referred to as a “flange section” of the dielectric substrate 100. In FIG. 1, a dotted line denoted by reference sign “BD” represents a boundary between the first part 101 and the second part 102. This boundary will also be hereinafter referred to as a “boundary BD”.

The second part 102 is thinner than the first part 101. The surface 120 described above is a surface on the lowermost side of the first part 101 in FIG. 1, and is also a surface on the lowermost side of the second part 102. A surface 102S on the uppermost side of the second part 102 is present at a position lower than the surface 110 in FIG. 1.

When a process on the wafer W is to be performed in the semiconductor manufacturing apparatus, an annular member which is referred to as a “focus ring” and the like and not illustrated in the drawing is arranged around the wafer W. The surface 102S of the second part 102 is a part that supports such an annular member from the lower side. The surface 102S is a surface parallel to the surface 110.

An attraction electrode layer 130 is provided inside the first part 101 of the dielectric substrate 100. The attraction electrode layer 130 is a thin planar layer made of a metallic material containing palladium as a principal component, and is arranged to be parallel to the surface 110. As a material of the attraction electrode layer 130, molybdenum, platinum, tungsten, and the like may be used in addition to palladium.

For example, a plurality of alumina particles may be arranged inside the attraction electrode layer 130. In this case, the “principal component” of the material constituting the attraction electrode layer 130 means a principal component of a metal portion excluding the alumina particles.

When a voltage is applied to the attraction electrode layer 130 from the outside via a feed line which is not illustrated in the drawing, an electrostatic force is generated between the surface 110 and the wafer W, whereby the wafer W is attracted and held. As a configuration of the above-described feed line, various configurations in related art can be adopted. The single attraction electrode layer 130 may be provided as a so-called “monopolar” electrode as in the present embodiment, but two attraction electrode layers 130 may also be provided as so-called “bipolar” electrodes. The attraction electrode layer 130 corresponds to a “conductor layer” in the present embodiment.

In addition to the above-described attraction electrode layer 130, an RF electrode layer 140 is embedded inside the first part 101. The RF electrode layer 140 is provided as one of a pair of counter electrodes for generating plasma in the semiconductor manufacturing apparatus. The other of the counter electrodes is provided at a position on an upper side relative to the electrostatic chuck 10 in the semiconductor manufacturing apparatus. When a high-frequency alternating-current voltage is applied between these counter electrodes, plasma is generated on the upper side of the wafer W and used for a process such as film deposition and etching on the wafer W.

The RF electrode layer 140 is a thin planar layer made of a metallic material containing palladium as a principal component, as in the attraction electrode layer 130. As a material of the RF electrode layer 140, molybdenum, platinum, tungsten, and the like may be used in addition to palladium.

For example, a plurality of alumina particles may be arranged inside the RF electrode layer 140. In this case, the “principal component” of the material constituting the RF electrode layer 140 means a principal component of a metal portion excluding the alumina particles.

The RF electrode layer 140 is embedded at a position closer to the surface 120 side than the attraction electrode layer 130. As in the attraction electrode layer 130, the RF electrode layer 140 is arranged to be parallel to the surface 110. The RF electrode layer 140 is a single electrode which is substantially circular in top view. In top view, a center of the RF electrode layer 140 matches a center of the dielectric substrate 100.

A voltage is applied to the RF electrode layer 140 via a feed line which is not illustrated in the drawing. The feed line may be connected to an external power source, for example, through a through hole formed in the base plate 200 described later, and may be electrically connected to a metal portion of the base plate 200. As a configuration of the above-described feed line, various configurations in related art can be adopted. The RF electrode layer 140, together with the above-described attraction electrode layer 130, corresponds to a “conductor layer” in the present embodiment.

A space SP is formed between the dielectric substrate 100 and the wafer W. When a process such as etching is performed in the semiconductor manufacturing apparatus, helium gas for temperature regulation is supplied to the space SP from the outside via a gas hole which is not illustrated in the drawing. When the helium gas is caused to be present between the dielectric substrate 100 and the wafer W, a thermal resistance between the dielectric substrate 100 and the wafer W is regulated, and according to this, a temperature of the wafer W is maintained at an appropriate temperature. It is noted that the gas for temperature regulation to be supplied to the space SP may be a gas of a type different from helium.

A seal ring 111 and a dot 112 are provided on the surface 110 which serves as the placement surface, and the space SP described above is formed around the seal ring 111 and the dot 112.

The seal ring 111 is an annular protrusion provided at a position corresponding to an outermost circumference of the first part 101 to define the space SP. An upper end of the seal ring 111 becomes a part of the surface 110 and abuts against the wafer W. It is noted that the seal ring 111 may include a plurality of seal rings 111 provided to divide the space SP. With such a configuration, a pressure of the helium gas in each of the spaces SP can be individually regulated, and a surface temperature distribution of the wafer W during the process can be set to be close to uniformity.

In top view, an end part on an outermost peripheral side of the seal ring 111 may match an end part on an outermost peripheral side of the first part 101, or may be located at a position on an inner side relative to the end part on the outermost peripheral side of the first part 101. In any case, the first part 101 is a part that includes the entire surface 110 on which an object to be processed is placed in top view, and is a part having a substantially constant thickness.

A part denoted by reference sign “116” in FIG. 1 is a bottom of the space SP. Hereinafter, this part may also be referred to as a “bottom 116”. The seal ring 111 is formed as a result of digging a part of the surface 110 to a position of the bottom 116 together with the dot 112 which will be described next.

The dot 112 is a circular protrusion which protrudes from the bottom 116. The dot 112 includes a plurality of dots 112 to be provided. The plurality of dots 112 are substantially uniformly distributed and arranged on the placement surface of the dielectric substrate 100. An upper end of each of the dots 112 becomes a part of the surface 110 and abuts against the wafer W. By providing the plurality of thus configured dots 112, warping of the wafer W is reduced.

The base plate 200 is a substantially disk-shaped member which supports the dielectric substrate 100. The base plate 200 is made of, for example, a metallic material such as aluminum. A surface 210 on the upper side in FIG. 1 in the base plate 200 serves as a “surface to be joined” which is joined to the dielectric substrate 100 via the joining layer 300. An outer shape of the surface 210 in top view is substantially the same as an outer shape of the second part 102 in top view.

The joining layer 300 is a layer provided between the dielectric substrate 100 and the base plate 200 to join those components. The joining layer 300 is obtained by causing an adhesive made of an insulating material to be cured. In the present embodiment, a silicone adhesive is used as the above-described adhesive. It is noted however that the joining layer 300 may be obtained by causing an adhesive of other types to be cured. In any case, in order that a thermal resistance between the dielectric substrate 100 and the base plate 200 is reduced, a material with a highest possible thermal conductivity is preferably used as the material of the joining layer 300.

An insulating film may be formed on a surface of the base plate 200. As the insulating film, for example, an alumina film formed by thermal spraying can be used. When the surface of the base plate 200 is covered by the insulating film, it is possible to increase an insulation withstand voltage of the base plate 200.

A coolant flow path 250 through which a coolant flows is formed inside the base plate 200. When the process such as etching is performed in the semiconductor manufacturing apparatus, the coolant is supplied from the outside to the coolant flow path 250, and according to this, the base plate 200 is cooled down. Heat generated in the wafer W during the process is transferred to the coolant via the helium gas in the space SP, the dielectric substrate 100, and the base plate 200, and the heat is exhausted to the outside together with the coolant. The supply and exhaustion of the coolant to and from the coolant flow path 250 are performed via openings which are not illustrated in the drawing and which are formed in a surface 220 opposite to the surface 210 in the base plate 200. The coolant flow path 250 is formed to pass through not only a range overlapping with the first part 101 in top view but also a range overlapping with the second part 102. Due to this, an annular member placed on the surface 102S is also cooled down by the coolant passing through the coolant flow path 250.

During manufacture of the electrostatic chuck 10 or the like, peeling may occur at an interface between the dielectric substrate 100 and the attraction electrode layer 130, and a gap may be formed therebetween. Similarly, peeling may occur at an interface between the dielectric substrate 100 and the RF electrode layer 140, and a gap may be formed therebetween. Such a gap is undesirable because it may locally increase thermal resistance or may cause damage to the dielectric substrate 100.

The present inventors have conducted intensive studies on conditions under which the above-described peeling occurs. As a result, the present inventors have obtained a new finding that the above-described peeling tends to occur when a total thickness of conductor layers such as the attraction electrode layer 130 provided inside the dielectric substrate 100 and an overall thickness of the dielectric substrate 100 satisfy a predetermined condition.

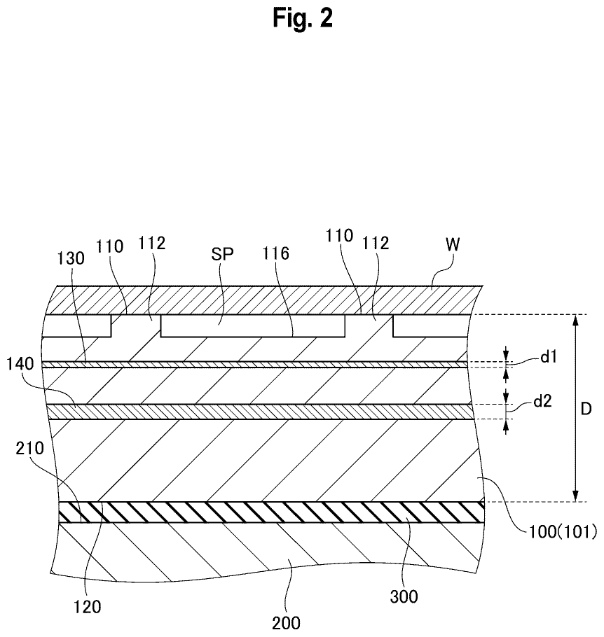

This condition will be described below. FIG. 2 illustrates an enlarged view of a part of the configuration in FIG. 1. In FIG. 2, “d1” represents a thickness of the attraction electrode layer 130. The thickness of the attraction electrode layer 130 is hereinafter also referred to as a “thickness d1”, or simply referred to as “d1”. The thickness d1 is, for example, about 3μm.

In FIG. 2, “d2” represents a thickness of the RF electrode layer 140. The thickness of the RF electrode layer 140 is hereinafter also referred to as a “thickness d2”, or simply referred to as “d2”. During the process on the wafer W, a current flowing through the RF electrode layer 140 is larger than a current flowing through the attraction electrode layer 130. To suppress Joule heat generated in the RF electrode layer 140, it is preferable that the thickness d2 be set to be equal to or larger than 10μm. In many cases, the thickness d2 is set to be larger than the thickness d1. The thickness d2 is, for example, about 20 μm.

The “thickness” of each conductor layer means a dimension of the conductor layer in a direction perpendicular to the placement surface. In a case where the dimension varies depending on a location, the “thickness” means an average value of the dimension over the entire conductor layer. In addition, in a case where a locally thick portion is provided in a very small part of the conductor layer due to manufacturing convenience or the like, the “thickness” of the conductor layer is calculated as an average value of an overall thickness of the conductor layer excluding the portion.

In FIG. 2, “D” represents an overall thickness of the dielectric substrate 100. The thickness is equal to a distance from the surface 110 as the placement surface to the surface 120, and can also be regarded as a thickness of the first part 101. Such a thickness is hereinafter also referred to as a “thickness D”, or simply referred to as “D”. The thickness D is often set within a range from 1.5 mm to 6 mm, for example.

As described above, a plurality of conductor layers are provided at mutually different height positions inside the first part 101 of the dielectric substrate 100. The “height position” means a position in a direction perpendicular to the placement surface. Regarding the plurality of conductor layers, an overall thickness obtained by summing respective thicknesses of the conductor layers is hereinafter also referred to as a “total thickness sd”, or simply referred to as “sd”. For example, in the configuration of the present embodiment, in a case where the thickness d1 of the attraction electrode layer 130 is 3 μm and the thickness d2 of the RF electrode layer 140 is 20 μm, sd=3+20=23 μm is satisfied.

The total thickness sd is obtained by summing thicknesses of all conductor layers provided at mutually different height positions inside the first part 101 of the dielectric substrate 100. For example, even in a case where the attraction electrode layer 130 is a so-called “bipolar” electrode and two attraction electrode layers 130 are arranged at the same height position, a value of sd is 23 μm, which is the same as described above. The conductor layers may include, in addition to the attraction electrode layer 130 and the RF electrode layer 140 as in the present embodiment, an embedded heater for heating the dielectric substrate 100, or the like.

According to experiments and the like conducted by the present inventors, a new finding has been obtained that in a case where the total thickness sd and the thickness D are set to satisfy a condition represented by the following expression (1), peeling between the dielectric substrate 100 and the conductor layers can be sufficiently suppressed. In the expression (1), a unit of sd is “μm”, and a unit of D is “mm”.

$$sd < - 10.5 \times D + 7 4.5 \qquad ( 1 )$$

For example, in a case where the thickness D of the dielectric substrate 100 is 5.3 mm, a value of a right side of the expression (1) is 18.85. Thus, in a case where the value of the total thickness sd is 23(3 μm+20 μm), the condition of the expression (1) is not satisfied, and peeling between the dielectric substrate 100 and the conductor layers tends to occur.

In a case where the thickness D of the dielectric substrate 100 is 4.6 mm, a value of the right side of the expression (1) is 26.2. Thus, in a case where the value of the total thickness sd is 23(3 μm+20 μm), the condition of the expression (1) is satisfied, and peeling between the dielectric substrate 100 and the conductor layer tends not to occur.

In electrostatic chucks in recent years, the thickness of the dielectric substrate is generally set to be equal to or smaller than 6 mm. The present inventors manufactured electrostatic chucks 10 having various configurations, and observed presence or absence of peeling after the manufacture. As a result, it was confirmed that, for all electrostatic chucks 10 in which the thickness D of the dielectric substrate 100 was equal to or smaller than 6 mm, peeling did not occur when the condition of the expression (1) was satisfied, whereas peeling occurred when the condition of the expression (1) was not satisfied. The same applied to a case where three or more conductor layers were provided at mutually different positions in the first part 101 of the dielectric substrate 100. By setting the thickness sd and the thickness D to satisfy the condition of the expression (1), peeling between the dielectric substrate 100 and the conductor layers can be sufficiently suppressed.

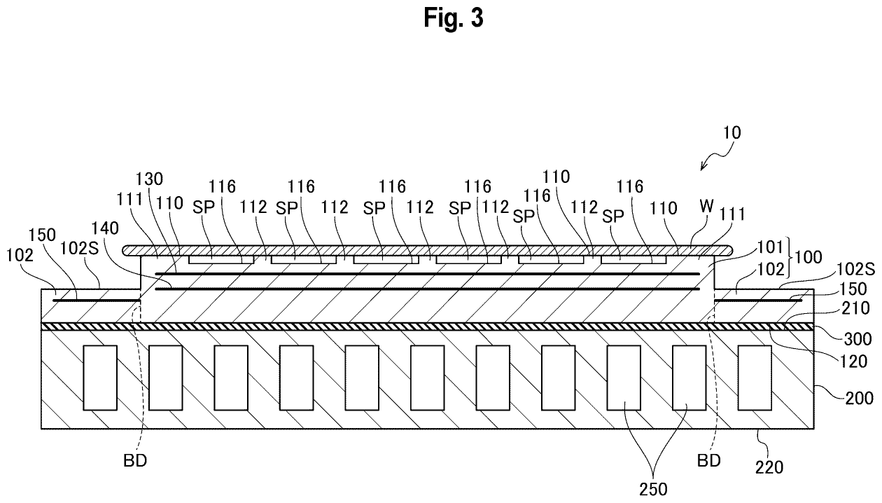

In the electrostatic chuck 10 having a configuration in which the second part 102 (flange section) is provided on the dielectric substrate 100 as in the present embodiment, a conductor layer may also be provided inside the second part 102. For example, in a modification illustrated in FIG. 3, an RF electrode layer 150 is provided inside the second part 102.

Even in such a case, as the total thickness sd in the expression (1), a value that is calculated without adding a thickness of the RF electrode layer 150 is used. That is, the total thickness sd is calculated as a sum of only thicknesses of the respective conductor layers provided inside the first part 101. The same applies to a case where a part of the RF electrode layer 150 in FIG. 3 extends into the first part 101 beyond a boundary BD, and the total thickness sd is calculated without adding the thickness of the RF electrode layer 150.

The present embodiment has been described above with reference to the specific examples. However, the present disclosure is not limited to these specific examples. Configurations obtained by adding appropriate design modifications to these specific examples by a person skilled in the art are also within the scope of the present disclosure as long as the configurations have a feature of the present disclosure. Each of the elements included in each of the specific examples described above and arrangements, conditions, shapes, and the like of the elements are not limited to those illustrated and can be modified as appropriate. For each of the elements included in each of the specific examples described above, a combination can be appropriately changed as long as a technical contradiction does not occur.

What is claimed is:

1. An electrostatic chuck comprising:
a dielectric substrate including a placement surface on which an object to be processed is placed; and
a plurality of conductor layers provided at mutually different height positions inside the dielectric substrate, wherein when a total thickness of the respective conductor layers is defined as sd (μm) and a thickness of the dielectric substrate is defined as D (mm),
the following condition: sd<−10.5×D+74.5 is satisfied.

2. The electrostatic chuck according to claim 1, wherein the plurality of conductor layers include an RF electrode layer.

3. The electrostatic chuck according to claim 2, wherein the RF electrode layer has a thickness equal to or larger than 10 μm.

4. The electrostatic chuck according to claim 2, wherein the RF electrode layer contains palladium as a principal component.

5. The electrostatic chuck according to claim 1, wherein the dielectric substrate contains alumina as a principal component.

6. The electrostatic chuck according to claim 1, wherein
the dielectric substrate includes
a first part and a second part, the first part including the placement surface, the second part protruding from an outer peripheral end of the first part further toward an outer peripheral side, the second part being thinner than the first part, and
the sd is a total thickness of the respective conductor layers provided in the first part.
